(19) United States
(12) Patent Application Publication
(10) Pub. No.: US 2010/0110633 A1
(43) Pub. Date: May 6, 2010

(54) INTEGRATED ACTIVE COOLED CABINET/RACK FOR ELECTRONIC EQUIPMENTS

(76) Inventor: Yekutiel Gigushinsky, Herzliya (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(21) Appl. No.: 12/594,216

(22) PCT Filed: Apr. 6, 2008
(86) PCT No.: PCT/IL08/00474

§ 371 Date: Jan. 10, 2010

Related U.S. Application Data
(60) Provisional application No. 60/910,216, filed on Apr. 5, 2007.

(51) Int. Cl. H05K 7/20; F28F 13/00

(52) U.S. Cl. 361/695; 165/80.2; 361/694

(57) ABSTRACT

An integrated active cooled cabinet/rack for electronic equipments. An aspect of the present invention is to provide a control unit for the cabinet, that enables individual equipment monitoring and control and thereby ensure that the equipment housed in the cabinet and generating the highest level of heat is cooled down to an acceptable preset temperature.

### FIELD OF THE INVENTION

The present invention related in general to electronic equipment cabinets and more particularly, the invention relates to an integrated, active cooling cabinet/rack designed for housing electronic equipment. The cabinet is capable of adjusting to the cooling requirements of one or more individual electronic items housed in the cabinet.

### BACKGROUND OF THE INVENTION

Electronic equipment cabinets are intended to house various types of communications and/or computerized equipment, including active electronic and optical systems and passive mechanical cross-connect and splicing fields. The cabinets are required to protect the electronics equipment from a wide range of temperatures, to cool the heated electronic equipment/computers in the cabinet enclosure, and to remove the heat from the equipment/computers.

Prior art electronic equipment cabinets are cooled down in several methods, whereas in all prior art methods the cabinet is cooled as a whole, disregarding the amount of air and cooling required by each one and type of the hosted equipment and without ensuring and controlling the required cooling of any individual electronic equipment housed in the cabinet. It should be noted that cooling a cabinet as a whole, does not provide the required amount of air and cooling to each of the individual electronic units installed in the cabinets—which results in over heating of the electronic equipment, even when the all cabinet/room is cooled. In one common method, electronic equipment cabinets are kept in designated rooms, where the whole room is cooled down. This method often causes people working in the designated room to be very cold while the electronic equipments housed in the cabinets are still overheating. In existing computer centers, the amount of air supplied by the air conditioning units is much bigger than the amount of air which circulates inside the cabinets. Only a portion of the air is flowing through the cabinets and most of it is circulating and cooling the room. Typically, in order to supply X CFM (Cubic Feet per Minute) of air into a cabinet, 3X CFM of air has to be supplied to the room/raised floor by the air conditioning units, without being able to ensure that each one of the cabinets or individual electronic equipment inside the cabinets gets the right amount of air and temperature. as a result, the air conditioning units supplying cooled air, 3 times more than the amount required by the electronic equipment.

In another method, cold air is supplied from the bottom of the cabinets, but without any possibility to control and ensure that the right amount of cooling air is supplied to each unit of electronic equipment housed in the cabinet, as required. In other prior art cabinets, heat exchanger that cools the air is installed in or adjacent to the cabinet and cooled air is supplied at the bottom or the top of the cabinet to cool the cabinet as a whole without the ability to control and ensure that each individual electronic equipment receives the required amount cooling. A system that includes a heat exchanger must be connected to chilled water piping, reduce the usable height of the cabinets and prevents a free and open access to the electronic equipment and cabling.

Typically, electronic equipments have frontal suction inlets whereas the hot air flows out from the back of the electronic equipments.

The electronic equipment/computers housed in the cabinet generate large amounts of heat that must be removed to avoid equipment failure. Furthermore, each electronic item often generates a different amount of heat from other items and thus its cooling requirement is also different from that required by other items.

There is therefore a need for and it would be advantageous to have electronic equipment cabinet that enable individual equipment monitoring and control and thereby ensure that the equipment housed in the cabinet and generating the highest level of heat is cooled down to an acceptable preset temperature.

The term “diffuser”, as used herein refers to a means for deflecting air from an outlet, whereas the outlet can be an opening in a sleeve in which the air is flowing.

### SUMMARY OF THE INVENTION

The principle intention of the present invention includes providing a cabinet for housing one or more electronic equipments placed on racks, having a front side, a back side and, two sided sides and a top side, whereas the cabinet includes:

(a) a cool air supply unit which includes an air propelling device, for example, a blower; and

(b) one or two hollow posts disposed at the corners of the front side of the cabinet, whereas the hollow posts include multiple diffusers for dispersing cool air.

The cool air supply unit is operatively connected to an external source of cool air, whereas the air propelling device compresses cool air from the external source of cool air into the hollow posts. The external source of cool air is selected from the group of sources including: the ambient air in the room where the cabinet is operating, air conditioned raised floor and a canal connected to an air condition unit. The compressed cool air flows from inside the hollow posts, through the diffusers towards each of the electronic equipments placed on the cabinet racks, thereby cooling each of the electronic equipments. It should be noted that the typically, electronic equipments have air suction inlets in front of the devices and the hot air is exhausted from the back of the devices. It should be further noted that the front side, back side, two sided sides and top side can be closed or open, without interfering with the operation and cooling of the cabinet.

Preferably, the cabinet further includes a control unit for controlling the flow of air to each of the electronic equipments installed in the cabinet, thereby ensuring that each of the electronic equipments operates within the recommended range of operational temperature. The control unit includes multiple temperature sensors and a processing unit. At least one sensor is disposed at the back of each of the racks for sensing the temperature of the air coming out of each of the electronic equipments. The processing unit processes the collected temperature data and determines the maximal temperature coming out of the electronic equipments installed in the cabinet. Based on the maximal temperature, the control unit determines if the air propelling device should increase the compression of the cool air into the hollow posts.

An aspect of the present invention is to provide a method for reducing the operational temperature of each one of the electronic equipments placed on racks inside a cabinet, by providing a cool air supply unit having an air propelling device, and providing one or two hollow posts disposed at the corners of said front of the cabinet, wherein each of the hollow posts includes diffusers for dispersing cool air directly and individually to each of the electronic equipment installed in the cabinet.

Another aspect of the present invention is to provide a method for controlling the operational temperature of each one of the electronic equipments placed on racks inside the cabinet. The method includes providing a control unit, having a processing unit, and capable of collecting temperature data from the air outlet of each the electronic equipment installed in the cabinet, using temperature sensors. The processing unit processes the temperature data and determines the maximal temperature coming out of the electronic equipments. Based on the maximal temperature, the control unit determines if the air propelling device should increase the compression of the cool air into the hollow posts.

Preferably, the method further comprising the steps of providing a sensor for sensing the temperature of the cool air supplied by the cool air supply unit, thereby determining the incoming air temperature; and processing the incoming temperature to determine the exact air capacity needed to maintain the required operating temperature of electronic equipments installed in the cabinet. It should be noted that by monitoring both the incoming temperature (T1) and the maximal temperature (T2ₘₐₓ), the control unit can automatically adjust the exact air capacity needed to maintain the required operating temperature of each electronic. The control unit computed ΔT=T2ₘₐₓ−T1 to determine the cooling air load that is needed to maintain an appropriate T2ₘₐₓ. That is, if either T2ₘₐₓ or T1 increase, more cooling air load is needed, and if either T2ₘₐₓ or T1 decrease, less cooling air load is needed.

It should be noted that most of the diffusers disperse cool air directly and individually towards the suction inlets of each of the electronic equipments, but some of the diffusers may disperse cool air also towards the sides of the electronic equipments.

Preferably, the cabinet of the present invention further includes a front door disposed at the front of the cabinet. The cabinet may also include side panels, a back panel and a top panel to enclose the cabinet. In embodiments of the present invention a back door is disposed at the back of the cabinet.

The doors and/or panels are preferably made of rigid materials such as glass, wherein the rigid materials are clear, opaque or partially opaque. The doors and the panels enable fast access to the electronic equipments installed in the cabinet. By providing doors and/or panels that can be view through, monitoring of the electronic equipments installed in the cabinet is provided.

In embodiments of the present invention, one or more of the doors and/or panels are perforated to allow the air coming out of the electronic equipments to flow out of the cabinet into the room where the cabinet operates. It should be noted that the perforation of the doors and/or panels does not interfere with the operation and cooling of the cabinet.

In embodiments of the present invention, the doors and/or panels are a silent.

In embodiments of the present invention, the cabinet further includes one or more communication wiring ducts, with free access to the wiring and without interfering with the operation and cooling of the cabinet.

In embodiments of the present invention, the cabinet further includes one or more electric wiring posts, with free access to the wiring without interfering with the operation and cooling of the cabinet.

In preferred embodiments of the present invention, the front door includes an electrically controlled unlocking mechanism, wherein upon a failure to reduce the maximal temperature below a preset threshold temperature, the unlocking mechanism opens said front door.

### BRIEF DESCRIPTION OF THE DRAWINGS

The present invention will become fully understood from the detailed description given herein below and the accompanying drawings, which are given by way of illustration and example only and thus not limitative of the present invention, and wherein:

FIG. 1 is a schematic perspective view illustration of an integrated, active cooled cabinet for electronic equipment, according to embodiments of the present invention.

FIG. 2 is a front view illustration of an integrated, active cooled cabinet for electronic equipment, according to embodiments of the present invention, having a blower connected to a cool air source coming from the floor.

FIG. 3 is a cross sectional view taken along line A-A′ of FIG. 2.

FIG. 4 is a front view illustration of an integrated, active cooled cabinet for electronic equipment, according to embodiments of the present invention, having a blower connected to a cool air source coming from the ceiling.

FIG. 5 is a front view illustration of a multi-cabinet system, according to embodiments of the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided, so that this disclosure will be thorough and complete, and will fully convey the scope of the invention to those skilled in the art.

Unless otherwise defined, all technical and scientific terms used herein have the same meaning as commonly understood by one of ordinary skill in the art to which this invention belongs. The methods and examples provided herein are illustrative only and not intended to be limiting.

By way of introduction, the principal intentions of the present invention include providing an integrated active cooled cabinet/rack for electronic equipments. An aspect of the present invention is to provide a controlled cooling of the cabinet, that enables individual equipment cooling and monitoring and thereby ensure that the equipment housed in the cabinet and generating the highest level of heat is cooled down to an acceptable preset temperature.

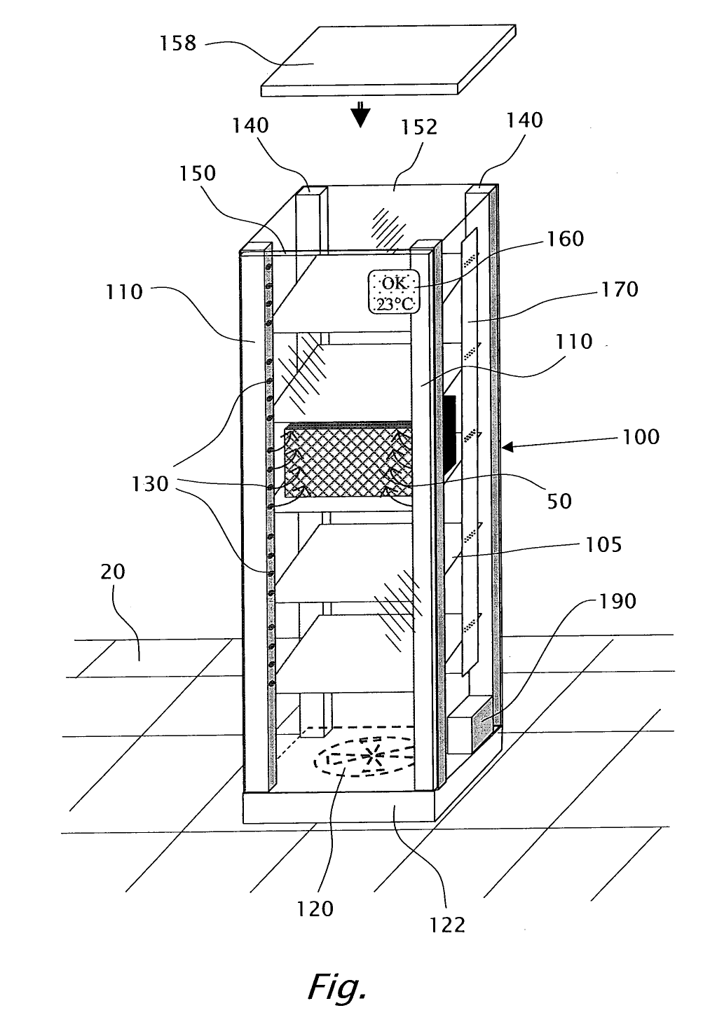

Reference is now made to FIG. 1, which a schematic perspective view illustration of an integrated, active cooled cabinet 100 for electronic equipment 50, according to embodiments of the present invention. Cabinet 100 includes a cool air supply unit, posts 110 for channeling high pressure cool air towards racks 105, through diffusers 130 and control unit 190. Cabinet 100 may further include one or more communication panels 170, electrical wiring posts 140.

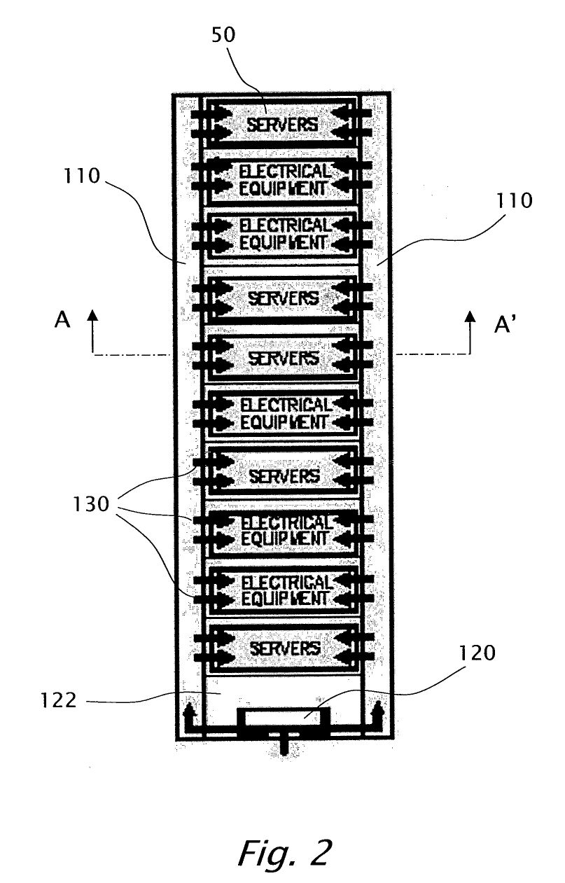

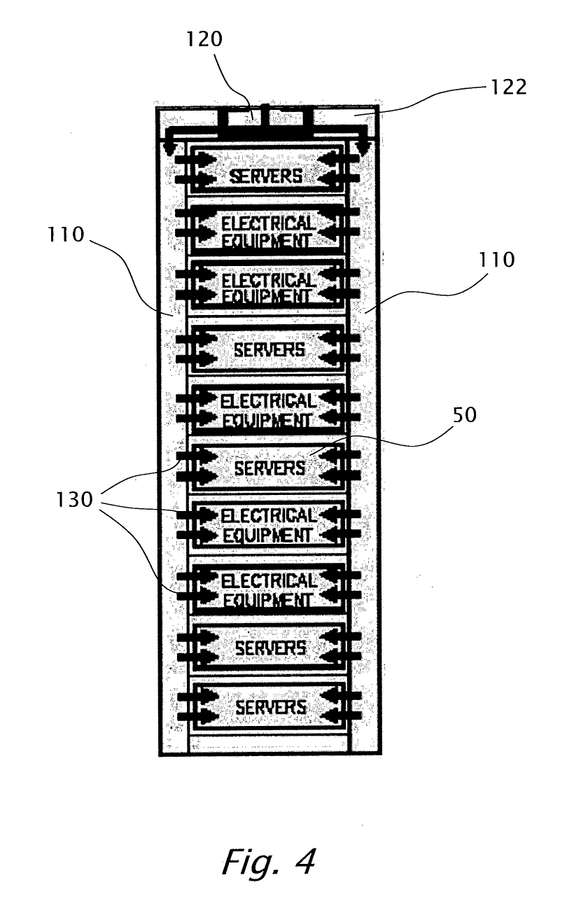

Preferably, the cool air supply unit includes an air propelling device such as blower 120 which is operatively connected to an external source of cool air such as air conditioned raised floor or air conditioned room. Reference is also made to FIG. 2, which is a front view illustration of cabinet 100, having blower 120 operatively connected to a cool air source coming from the floor, typically raised floor 20, and to FIG. 4, which is a front view illustration of cabinet 100, according to embodiments of the present invention, having blower 120 operatively connected to a cool air source coming from the ceiling.

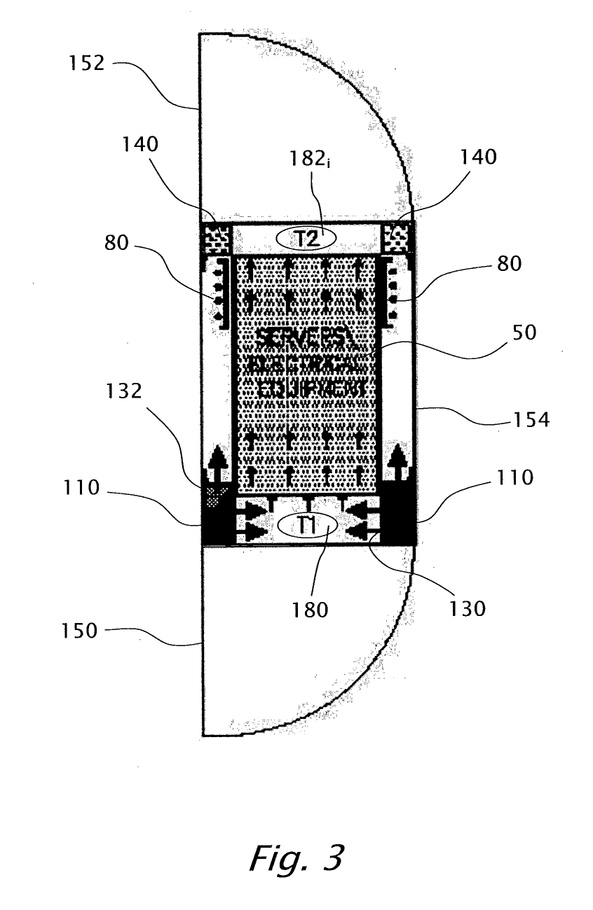

The cool air supply unit draws cool air, typically from an external source, and pumps the cool air at high, pre designed pressure, into posts 110. Posts 110 are designed to accommodate the cooled airflow which pours out of the designated diffusers 130 directly towards the air suction inlets of each individual electronic item 50 housed inside cabinet 100. Each individual electronic item 50 is supplied with the proper amount of cooled airflow. Reference is also made to FIG. 3, which is a cross sectional view taken along line A-A′ of FIG. 2, wherein cabinet 100 does not include ceiling 158 or ceiling 158 is removed. Preferably, cabinet 100 further include a front door 150 a back door or panel 152 and optionally side panels 154. Cabinet 100 may further include ceiling 158. The doors and/or panels (150, 152 and 154) and/or ceiling 158 can be made of clear material such that the electronic equipment can be seen through the clear doors and/or panels (150, 152 and 154) and/or ceiling 158. The doors/panels (150, 152 and 154) and/or ceiling 158 may be partially clear, opaque, or perforated. It should be noted that the cooling process of cabinet 100 works well, weather doors/panels (150, 152 and 154) and/or ceiling 158 are assembled or not.

Optionally, posts 110 also include diffusers 132 (FIG. 3), which disperse cool air to the sides of electronic equipments 50.

The dispersing of cooled air from posts 110 to each of the individual electronic items 50 is automatically regulated by control unit 190, and directed directly towards suction inlet of each of the individual electronic equipment 50. Control unit 190 includes temperature sensor 180 that measures the temperature (T1) of the incoming cool air, and multiple sensors 182 that measure the air temperature (T2ᵢ) coming out of each electronic equipment 50. Control unit 190 determines temperature being the highest measured temperature T2ᵢ. If T2ₘₐₓ is greater than a preset threshold value (Tₜₕᵣ), control unit 190 increases the flow of cooled air supply, for example, by increasing the rotational speed of blower 120, until T2ₘₐₓ≦Tₜₕᵣ. As more cool air is flowing through the overheated electronic equipment 50 having T2=Tₘₐₓ, Tₘₐₓ decreases gradually until corresponding sensor 182ᵢ senses a temperature T2ₘₐₓ≦Tₜₕᵣ.

It should be noted that by reducing T2ₘₐₓ to be below Tₜₕᵣ, control unit 190 ensures that ALL electronic equipments 50 in cabinet 100 have a T2ᵢ≦Tₜₕᵣ.

Cabinet 100 is structured such that it allows easy frontal and/or posterior access to each of the individual electronic items 130 housed inside cabinet 100. Furthermore, preferably, each of the individual electronic equipment 50 can also be easily viewed from the front and/or back of cabinet 100.

Cabinet 100 preferably includes posts 140, which are designated for electric wiring of cabinet 100, whereas there is a complete separation between the inner space of cooling posts 110 and the inner space of wiring posts 140. Cables, including electricity supply, may reach posts 140, or other parts of cabinet 100, from the floor, the ceiling or from anywhere else, whereas there is no obstruction in the operation of the cooling system of cabinet 100. The electric wiring typically serves the electric needs of electronic equipments 50.

Cabinet 100 preferably include one or more communication panels 170, which are designated for communication wiring of cabinet 100, whereas there is no obstruction in the operation of the cooling system of cabinet 100. The communication wiring typically serves the communication wiring needs of electronic equipments 50.

Optionally, cabinet 100 further includes display 160 which displays data related to cabinet 100. For example, control panel 190 can display on display 160 the current T2i of each individual electronic equipment, T2ₘₐₓ, T1, the humidity inside cabinet 100, Tₜₕᵣ and the heat dissipation load, for example, in KW. If T2ᵢ≦Tₜₕᵣ, display 160 displays, for example, a green OK message, and if T2ᵢ≦Tₜₕᵣ, display 160 displays, for example, temperature T2ₘₐₓ in red illumination. More than one display 160 can be utilized, for example, for each rack. All controlled information and alarms such as the data displayed on display 160, can be transmitted to an external control system.

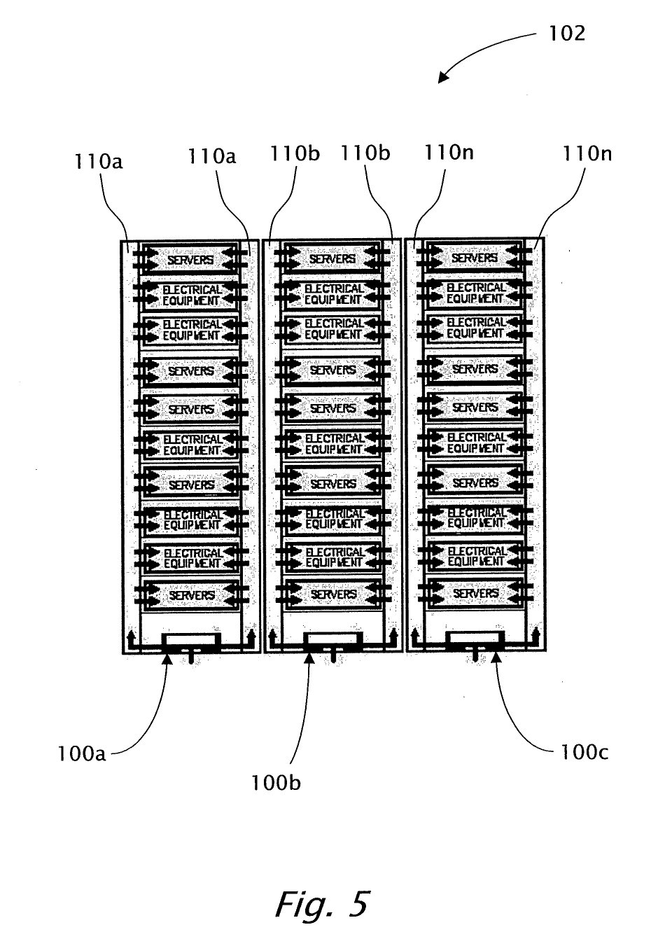

Preferably, cabinet 100 is a modular cabinet, and thereby can be connected to other cabinets 100, side-by-side. FIG. 5 illustrates an example multi-cabinet system 102, according to embodiments of the present invention, having three cabinets 100 attached to each other, side-by-side. Each cabinet 100 is still controlled and operated individually, and thereby each electronic equipment 50 is still controlled individually.

In embodiments of the present invention, cabinet 100 further includes a heat exchanger to controllably cool down ambient air. Thereby, there is no need for cabinet 100 to be connected to an external source of cooled air. Cabinet 100 including a heat exchanger is preferably controlled by increasing or decreasing the amount of water flowing through the heat exchanger.

In embodiments of the present invention, front door 150 and/or back door 152 of cabinet 100 include an electrically controlled unlocking mechanism, such as an electromagnet. Thereby, in case of a failure to reduce the current T2ₘₐₓ such that T2ₘₐₓ≦Tₜₕᵣ, the doors (150 and/or 152) open automatically. A for a preset period of time will cause control unit 190 to automatically open electrically controlled unlocking mechanism. Optionally, in case of a failure in the incoming flow of cool air can be caused by failure of the external air condition or failure of blower 120, the doors (150 and/or 152) open automatically. A failure in the incoming flow of cool air can be controlled by control unit 190, by checking the Ti is below some threshold temperature.

In embodiments of the present invention, the air propelling device such as blower 120 includes two devices, for example two blowers 120, such that one is a backup for the other. Typically, each blower 120 works at about 50% of the device capacity. When one blower 120 fails, at least partially, the second blower 120 provides the lost capacity of air propelling power.

In embodiments of the present invention, when a rack 105 is vacant, corresponding diffusers 130 and/or 132 are blocked from diffusing cool air.

An aspect of an active cooled cabinet of the present invention is to supply the required cooling air load, needed to dissipate the heat load of any electronic equipment 50 installed inside cabinet, directly to electronic equipment 50, regardless of the air conditioning needs of the room housing cabinet 100. Hence, cabinets 100 of the present invention significantly reduce the number of air conditioning units required to cool a server room and thereby significantly reduce the energy consumed for cooling computer rooms and computer centers. Cabinets 100 of the present invention automatically consumes substantially the exact air capacity needed to maintain the required operating temperature of electronic equipment 50, typically saving ⅔ of the total room air conditioning air flow, relative to prior art system. Control unit 190 computes: ΔT=T2ₘₐₓ−T1 to determine the cooling air load that is needed to maintain an appropriate T2ₘₐₓ. That is, if either T2ₘₐₓ or T1 increase, more cooling air load is needed, and if either T2ₘₐₓ or T1 decrease, less cooling air load is needed.

Although the present invention has been described with reference to the preferred embodiment and examples thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the following claims.

1. A cabinet for housing one or more electronic equipments placed on racks, having a front side, a back side, two sided sides and a top side, the cabinet comprising:
(a) a cool air supply unit comprising an air propelling device; and
(b) one or two hollow posts disposed at the corners of said front, wherein each of said hollow posts comprises diffusers for dispersing cool air,
wherein said cool air supply unit is operatively connected to an external source of cool air and said air propelling device compresses cool air from said external source of cool air into said hollow posts;
wherein said compressed cool air further flows through said diffusers for dispersing cool air towards each of said electronic equipments placed on said racks, thereby cooling each of said electronic equipments; and
wherein at least one of said front side, back side, two sided sides and top side is opened and wherein in said opened side does not interfere with the operation and cooling of the cabinet.

2. The cabinet as in claim 1 further comprising a control unit, wherein said control unit comprises:
i) a sensor at the back of each of said racks for sensing the temperature of the air coming out of each of said electronic equipments; and
ii) a processing unit,
wherein said processing unit processes said temperatures of said air coming out of each of said electronic equipments, thereby determining the maximal temperature coming out of said electronic equipments; and
wherein said processing unit processes said maximal temperature, thereby determining if said air propelling device should increase said compression of said cool air into said hollow posts.

3. The cabinet as in claim 2 further comprising a sensor for sensing the temperature of said cool air supplied by said cool air supply unit.

4. The cabinet as in claim 1, wherein said air propelling device is a blower.

5. The cabinet as in claim 1, wherein said diffusers disperse said cool air directly and individually towards the suction inlet of each of said electronic equipments.

6. The cabinet as in claim 1, wherein said diffusers disperse said cool air towards the sides of said electronic equipments.

7. The cabinet as in claim 1, wherein said external source of cool air is selected from the group including the ambient air in the room where the cabinet is operating, air conditioned raised floor and a canal connected to an air condition unit.

8. The cabinet as in claim 1 further comprising a front door.

9. The cabinet as in claim 1 further comprising a back door or a back panel.

10. The cabinet of claim 1, further comprising a front door and a back door or a back panel, said front and said back door or back panel being made of rigid materials such as glass, wherein said rigid materials are clear, opaque or partially opaque.

11. The cabinet as in claims 10, wherein said door is perforated and wherein said perforation of said door does not interfere with the operation and cooling of the cabinet.

12. The cabinet as in claims 10, wherein said door is a silent door.

13. The cabinet as in claim 1 further comprising one or more panels selected from the group consisting of a side panel and a ceiling.

14. The cabinet as in claims 10, wherein said panel is perforated and wherein said perforation of said panel does not interfere with the operation and cooling of the cabinet.

15. The cabinet as in claims 13, wherein said panel is a silent panel.

16. The cabinet as in claim 1 further comprising one or more communication wiring ducts, with free access to the wiring without interfering with the operation and cooling of the cabinet.

17. The cabinet as in claim 1 further comprising one or more electric wiring posts, with free access to the wiring without interfering with the operation and cooling of the cabinet.

18. The cabinet as in claim 9, wherein said front door comprises an electrically controlled unlocking mechanism, wherein upon a failure to reduce said maximal temperature below a preset threshold temperature, said unlocking mechanism opens said front door.

19. A method for reducing the operational temperature of each one of the electronic equipments placed on racks inside a cabinet, having a front side, a back side two sided sides and a top side, said method comprising the steps of:
(a) providing a cool air supply unit comprising an air propelling device; and
(b) providing one or two hollow posts disposed at the corners of said front of said cabinet, wherein each of said hollow posts comprises diffusers for dispersing cool air directly and individually to each one of the electronic equipment installed in the cabinet,
wherein said cool air supply unit is operatively connected to an external source of cool air and said air propelling device compresses cool air from said external source of cool air into said hollow posts; and
wherein said compressed cool air further flows through said diffusers for dispersing cool air towards each of said electronic equipments placed on said racks, thereby cooling each of said electronic equipments; and
wherein at least one of said front side, back side, two sided sides and top side is opened and wherein in said opened side does not interfere with the operation and cooling of the cabinet.

20. A method for controlling the operational temperature of each one of the electronic equipments placed on racks inside a cabinet, having a front side, a back side, two sided sides and a top side, said method comprising the steps of:
(a) providing a cool air supply unit comprising an air propelling device;
(b) providing one or two hollow posts disposed at the corners of said front of said cabinet,
wherein said cool air supply unit is operatively connected to an external source of cool air and said air propelling device compresses cool air from said external source of cool air into said hollow posts;
wherein each of said hollow posts comprises diffusers for dispersing cool air directly and individually to each one of the electronic equipment installed in the cabinet; and
wherein at least one of said front side, back side, two sided sides and top side is opened and wherein in said opened side does not interfere with the operation and cooling of the cabinet;
(c) providing a control unit comprising:
i) a sensor at the back of each of said racks for sensing the temperature of the air coming out of each of said electronic equipments; and
ii) a processing unit
(d) processing said temperatures of said air coming out of each of said electronic equipments, thereby determining the maximal temperature coming out of said electronic equipments; and
(e) processing said maximal temperature, thereby determining if said air propelling device should increase said compression of said cool air into said hollow posts.

21. The method as in claim 20 further comprising the step:
(f) providing a sensor for sensing the temperature of said cool air supplied by said cool air supply unit; and
(g) processing said temperature of said cool air, thereby determining the exact air capacity substantially needed to maintain the required operating temperature of electronic equipment.
